(19) United States
(12) Patent Application Publication
(10) Pub. No.: US 2023/0420542 A1
(43) Pub. Date: Dec. 28, 2023

(54) METHOD FOR PRODUCING A TRANSISTOR WITH A HIGH DEGREE OF ELECTRON MOBILITY, AND PRODUCED TRANSISTOR

(71) Applicants: FRAUNHOFER-GESELLSCHAFT ZUR FÖRDERUNG DER ANGEWANDTEN FORSCHUNG E.V., München (DE); FERDINAND-BRAUN-INSTITUT GGMBH, LEIBNIZ-INSTITUT FÜR HÖCHSTFREQUENZTECHNIK, Berlin (DE)

(72) Inventors: Elke MEISSNER, Erlangen (DE); Hans-Joachim WÜRFL, Berlin (DE)

(73) Assignees: FRAUNHOFER-GESELLSCHAFT ZUR FÖRDERUNG DER ANGEWANDTEN FORSCHUNG E.V., München (DE); FERDINAND-BRAUN-INSTITUT GGMBH, LEIBNIZ-INSTITUT FÜR HÖCHSTFREQUENZTECHNIK, Berlin (DE)

(21) Appl. No.: 18/253,358

(22) PCT Filed: Nov. 25, 2021
(86) PCT No.: PCT/EP2021/082913

§ 371 Date: May 17, 2023

(30) Foreign Application Priority Data
Nov. 25, 2020 (DE) 10 2020 214 767.1

(51) Int. Cl. H01L 29/66; H01L 29/778; H01L 29/78; H01L 23/373

(52) U.S. Cl. CPC H01L 29/66462; H01L 29/7786; H01L 29/7827; H01L 29/66522; H01L 29/66666; H01L 23/3731; H01L 23/3732; H01L 29/2003

(57) ABSTRACT

The invention relates to a method for producing a transistor with a high degree of electron mobility and to a transistor with a high degree of electron mobility. The method is characterized in that an epitaxial layer is first grown on a flat substrate, and the flat substrate is then completely removed from the bottom of the epitaxial layer, wherein a thermally conductive layer is applied onto the bottom of the epitaxial layer such that the thermally conductive layer contacts at least 80%, preferably at least 90%, particularly preferably at least 95%, in particular 100%, of the bottom of the epitaxial layer. The method is simple and inexpensive to carry out and provides a transistor which has a high degree of electron mobility, an improved electric output without backgating, and an improved heat dissipation. The method additionally allows a transistor to be provided with a vertical transistor structure.

A method for producing a transistor with high electron mobility is described, and a transistor with high electron mobility is provided. The method is characterized in that, initially, an epitaxial layer is grown onto a flat substrate, and that the flat substrate is then completely removed again from the bottom side of the epitaxial layer, wherein a thermally conducting layer is applied to the bottom side of the epitaxial layer so that the thermally conducting layer contacts at least 80%, preferably at least 90%, particularly preferably at least 95%, and in particular 100%, of the bottom side of the epitaxial layer. The method can be carried out easily and cost-effectively and provides a transistor that has high electron mobility, enhanced electrical power without back-gating, and improved heat dissipation. The described method additionally makes it possible to provide a transistor having a vertical transistor structure.

GaN is a broadband semiconductor having a wide band gap, which is ideally suited for power electronics devices. In connection with the fact that the use of a native GaN wafer as a substrate for the epitaxy of the component would be extremely expensive, other solutions that utilize inexpensive substrates such as silicon are widely used.

Traditional high electron mobility transistors (HEMTs) are produced on SiC or Si substrates as lateral components. Despite the advantage of the lateral 2DEG channel in GAN/AlGaN components, a vertical architecture would be desirable for power applications due to the positive effects with respect to the circuit design and the passive components.

GaN-based HEMT structures are known in the prior art and are commercially available. The HEMT structure is composed of an active surface including an AlGaN barrier on a GaN channel layer. A thick GaN layer doped with carbon or iron acts as an insulating barrier with respect the back side. Beneath the AlGaN/GaN interface, a two-dimensional electronic gas (“2DEG” for short) is generated due to the bending of the band that arises due to differences in the band gap and polarization fields. The 2DEG forms a highly laterally conducting channel, resulting in a fast-switching lateral component that is superior to other traditional power components.

The silicon substrate, which is considered to be cost-effective, but brings with it a host of drawbacks, is situated beneath the entire structure. The silicon substrate has high thermal and structural mismatch with respect to the GaN lattice. It is therefore known that a thick stack of layers (“buffer layers”) has to be deposited to absorb the strain and match the lattice. These buffer layers must be properly coordinated to avoid high wafer bow, which is not acceptable for the later processing of the component. Moreover, the adaptation of extraneous materials causes a large number of defects and dislocations (typically 10⁹/cm²), which are known to be harmful to component power.

Consequently, lattice and strain adaption layers, such as thicker insulating buffer or channel layers, which are inevitable on Si substrates limit and impede further developments. AlGaN barriers having a high aluminum content would be desirable developments to achieve multiple kV powers.

Moreover, not only are the conductivity and the floating potential of the Si substrate, which results in back-gating or breakdowns due to the failure of a component, a problem, but the heat dissipation is also a serious problem. The thermal conductivity of the Si substrate is poor, and the heat cannot be dissipated well by the thick Si substrate. To avoid this, thinning must be carried out, which is risky in terms of breakage of the chips. Moreover, the vertical thermal conductivity is additionally reduced as a result of the insertion of the strain and defect accommodation layers.

With respect to vertical GaN components, component concepts using GaN on Si wafers are not possible at all since the large number of additionally required layers act as potential barriers, and the vertical current flow is thus severely impeded.

In addition, it is known that the presence of the conductive Si substrate just a few μm beneath the active channel results in strong back-gating effects. This prevents the lateral co-integration of component structures that have a high potential difference with respect to one another, for example the integration of semi-bridge or full-bridge structures. Successful integration is only possible when the direct coupling of the substrate bias to the transistor channel is effectively suppressed. For example, it is known to achieve such an integration by implementing GaN transistors on silicon-on-insulator (SOI) layers with GaN epitaxy thereabove. This allows a monolithic integration, however at the expense of thermal conductivity. This is a considerable drawback for the use of SOI as an insulating medium.

As a result, it becomes apparent that the presence of the Si substrate itself is harmful to the performance of the GaN power component, and that much greater power is to be expected if the Si substrate were to be completely removed.

Of late, new solutions have been proposed, in which the Si substrate locally beneath the gate was removed locally, which resulted thus far in outstanding performance and made it possible to operate the transistor up to 3 kV (Dogmus, E. & Zegaoui, M., Appl. Phys. Expr., Volume 11, pg. 034102 et seq, 2018). The technique of local removal in some areas, however, is quite complicated and the Si substrate is still present in other areas. The local sputtering of an AlN rear side within the removed regions is complicated, and the presence of local AlN-filled regions, in addition to residual Si substrate, also results in differences in the mechanical behavior of the chip later in the packaging routes.

Proceeding from this, it was the object of the present invention to provide a method by which a transistor can be provided that does not have the disadvantages known in the prior art. In particular, the method should be able to be carried out easily and cost-effectively and provide a transistor that has high electron mobility, enhanced electrical power without back-gating, and improved heat dissipation. In particular, the method should enable an implementation of vertical transistor structures.

The object is achieved by the method having the features of claim 1 and by the transistor with high electron mobility having the features of claim 14. The dependent claims show advantageous refinements.

According to the invention, a method for producing a transistor with high electron mobility is provided, comprising the following steps:
a) growing an epitaxial layer, which comprises or consists of a semiconductor material, onto a front side of a flat substrate, the flat substrate being suitable
   i) for being removable from the epitaxial layer by chemical etching and/or dry etching; and/or
   ii) for being removable from the epitaxial layer by the application of laser radiation having a certain wavelength;
b) applying at least one lateral and/or vertical transistor structure to a front side of the epitaxial layer;
c) applying a temporary wafer to the front side of the epitaxial layer;
d) removing the flat substrate from the bottom side of the epitaxial layer;
e) applying a thermally conducting layer to the bottom side of the epitaxial layer; and
f) completely removing the temporary wafer,

characterized in that the flat substrate is completely removed from the bottom side of the epitaxial layer, and the thermally conducting layer is applied to the bottom side of the epitaxial layer so that the thermally conducting layer contacts at least 80%, preferably at least 90%, particularly preferably at least 95%, and in particular 100%, of the bottom side of the epitaxial layer.

The front side of the epitaxial layer is understood to mean the side of the epitaxial layer facing away from the flat substrate. A temporary wafer is understood to mean a wafer that, during the course of the method according to the invention, is initially applied to the front side of the epitaxial layer and is removed again later during the method. Contacting 100% of the bottom side of the epitaxial layer is understood to mean contacting of the bottom side of the epitaxial layer across its entire surface by the thermally conducting layer.

The method for providing the transistor is comparatively easy and cost-effective to carry out and allows the provision of transistors with low-inductance packages and circuits that have simple designs. The method is characterized by completely removing (that is, 100% removal), for example by lifting off and/or etching away, the flat substrate from the epitaxial layer. Compared to a merely local removal of the substrate from the epitaxial layer, which is known in the prior art, many advantages result, because no residues of the substrate or substrate layers remain on the bottom side of the epitaxial layer. In other words, a thermally conducting layer can be applied to the bottom side of the epitaxial layer across a large area. This improves the transfer of heat from the epitaxial layer to the thermally conducting layer, which increases the heat dissipation capability of the transistor, and thus increases the performance capability thereof, in particular over long operating periods.

Completely removing the substrate from the bottom side of the epitaxial layer is furthermore advantageous because the entire bottom side of the epitaxial layer then has the same properties for assembling further layers (for example, by way of bonding), and the further layers can be assembled with greater mechanical stability on the bottom side of the epitaxial layer, which increases the overall mechanical stability of the transistor. Moreover, completely removing the substrate increases the electron mobility of the epitaxial layer and improves the electrical power (without back-gating). In particular, no buffer layers are deposited between the flat substrate and the epitaxial layer, which makes a higher vertical breakdown voltage possible, both for lateral and for vertical transistors, because the breakdown is a function of the buffer layer thickness or n-drift layer thickness.

The method can be characterized in that the epitaxial layer comprises or consists of a semiconductor material (for example, a compound semiconductor), which is selected from the group consisting of GaN, AlN, AlₓGa₁₋ₓN, InGaN, InAlGaN, AlScN, Ga₂O₃, and combinations thereof, with x being a number between 0 and 1. The semiconductor material particularly preferably comprises GaN or consists thereof. The semiconductor material can include a doping, in particular a doping with an element selected from the group consisting of Si, Ge, O, C, Fe, Mn, and combinations thereof.

The method can furthermore be characterized in that the epitaxial layer is grown on, in the direction of the flat substrate, up to a height in the range of 200 nm to 50 μm.

Additionally, the epitaxial layer can have an extension of 25.4 mm to 300 mm in a direction parallel to the flat substrate.

The flat substrate used in the method can be suitable for allowing a layer comprising or consisting of a material selected from the group consisting of (optionally doped) GaN, AlN, AlₓGa₁₋ₓN, InGaN, InAlGaN, AlScN, Ga₂O₃, and combinations thereof (with x being a number between 0 and 1), to be grow on epitaxially.

The flat substrate used in the method can furthermore comprise or consist of a material that is selected from the group consisting of silicon carbide, sapphire, sapphire, and combinations and mixtures thereof. The material is preferably selected from the group consisting of silicon carbide and sapphire. The deposition of GaN heterostructures onto sapphire or silicon carbide is very well established. Compared to the epitaxy on a silicon substrate, a dislocation density that is lower by orders of magnitude (5×10⁷ to 1×10⁸ cm⁻² in the case of sapphire and in the order of magnitude of 10⁶ cm⁻² when using SiC) is achieved, which advantageously affects the performance and reliability of the transistors. Furthermore, a deposition of thick buffer layers, which enable lattice mismatch, is not required because the structural adaptation between GaN on sapphire or SiC compared to GaN on silicon is generally closer. The advantage of using sapphire as the material for the flat substrate is that flat sapphire substrates are available in a cost-effective manner, whereby the transistor can be provided more cost-effectively and thus more economically. The residual voltage in the transistor is lower due to the better structural adaptation between GaN and sapphire. Moreover, sapphire has a high material resistance with respect to higher epitaxy temperatures, whereby greater flexibility is provided with respect to epitaxial process windows or layer thicknesses.

The method can be characterized in that the flat substrate has a height in the range of 100 μm to 1.5 mm in the direction of the epitaxial layer.

The method can comprise applying at least one electrical front contact to an upper side of the epitaxial layer, wherein the application of the at least one electrical front contact is preferably carried out after the application of at least one lateral and/or vertical structure, which is selected from the group consisting of transistor, Schottky diode structure, p-n diode structure, PIN diode structure and combinations thereof, to the epitaxial layer, or after the removal of the temporary wafer.

The at least one electrical front contact can be applied using a material that has an electrical conductivity in the range of 10⁻⁶ Ωm to 10⁻⁸ Ωm.

Furthermore, the at least one electrical front contact can be applied using a material that has a thermal conductivity in the range of 10 to 2300 W/(m-K).

Additionally, the at least one electrical front contact can be applied using a material that comprises or consists of a metal, particularly preferably a metal selected from the group consisting of Au, Ag, Al, Pt, Ir, Ni, Cr, Ta, Mo, V, and alloys thereof.

Moreover, the at least one electrical front contact can be applied in such a way that the at least one electrical front-side contact has a height in the range of 50 nm to 10 μm in the direction of the epitaxial layer.

Apart from this, the at least one electrical front contact can be applied by way of deposition or bonding.

The method can be characterized in that the at least one lateral and/or vertical transistor structure is applied in the form of a layer.

The lateral and/or vertical transistor structure can comprise or consist of a semiconductor material, preferably AlₓGa₁₋ₓN and/or Ga₂O₃, which is optionally doped, with x being a number between 0 and 1.

Furthermore, the lateral and/or vertical transistor structure can be processed, wherein the processing preferably takes place after the structure has been applied to the epitaxial layer or after the temporary wafer has been removed, the processing step comprising a method that is selected from the group consisting of demetallization, wet-chemical etching, dry-chemical etching, insulator coating, ion implantation, diffusion, and combinations thereof.

The temporary wafer can be applied to the front side of the epitaxial layer by gluing on the temporary wafer.

The complete removal of the flat substrate from the bottom side of the epitaxial layer can be effected by way of chemical etching, dry etching, and combinations thereof. Etching-away is necessary if the substrate is transparent to the laser light of the laser that is used, that is no laser ablation can be carried out.

Furthermore, the complete removal of the flat substrate from the bottom side of the epitaxial layer can be effected by the application of laser radiation having a certain wavelength, preferably by lifting off the flat substrate by the application of laser radiation having a certain wavelength.

The thermally conducting layer on the bottom side of the epitaxial layer can comprise or consist of a material that has a specific thermal conductivity in the range of 10 to 2300 W/(m·K).

Furthermore, the thermally conducting layer can have been, or can be, applied to the bottom side of the epitaxial layer by way of deposition or bonding.

In a preferred embodiment, the thermally conducting layer on the bottom side of the epitaxial layer comprises or consists of a material that is electrically insulating, wherein the material preferably has a specific electrical resistance of at least 10¹⁰ Ωm. The electrically insulating material can furthermore be selected from the group consisting of AlN, TaC, SiN, diamond, and combinations thereof, wherein the material is preferably polycrystalline. Apart from this, the electrically insulating material can have a height in the range of 20 μm to 1.5 mm in the direction of the epitaxial layer.

In an alternative, preferred embodiment, the thermally conducting layer on the bottom side of the epitaxial layer comprises or consists of a material that is electrically conductive, wherein the material preferably has a specific electrical resistance of no more than 2·10⁻⁴ Ωm. Furthermore, the electrically conductive material can contact an n⁺-doped region of the epitaxial layer. In addition, the electrically conductive material can comprise or consist of a semiconductor material and/or metal, and particularly preferably a semiconductor material selected from the group consisting of Si, Ge, and combinations thereof. Apart from this, the electrically conductive material can have a height in the range of 50 nm to 5 μm in the direction of the epitaxial layer. This alternative embodiment of the method can provide vertical transistor architectures. As a result, all potential advantages that vertical transistors have compared to lateral transistors are achieved. This is not possible with known GaN-on-Si components since local substrate removal techniques must be employed, with all their specific drawbacks.

The method according to the invention can comprise applying at least one electrical back-side contact to a bottom side of the epitaxial layer. The electrical back-side contact is preferably applied to the bottom side of the epitaxial layer after the flat substrate has been removed, optionally after a local region of the thermally conducting layer has been removed. The electrical back-side contact can furthermore comprise or consist of a material that has a specific electrical resistance of no more than 2·10⁻⁴ Ωm. Additionally, the electrical back-side contact can comprise or consist of a material that has a specific thermal conductivity in the range of 150 to 380 W/(m·K). Apart from this, the electrical back-side contact can comprise or consist of a semiconductor material and/or metal, and particularly preferably a semiconductor material selected from the group consisting of Si, Ge, and combinations thereof.

The complete removal of the temporary wafer from the upper side of the epitaxial layer can be effected by way of a method selected from the group consisting of laser lift-off method, wet-chemical etching method, dry-chemical etching method, thermal method, thermally activated smart-cut method, and combinations thereof. Optionally, one of these removal methods is combined with an ion implantation method.

According to the invention, a transistor with high electron mobility is provided, comprising:
a) an epitaxial layer, which comprises or consists of a semiconductor material; and
b) at least one lateral and/or vertical transistor structure on an upper side of the epitaxial layer; and
c) a thermally conducting layer on a bottom side of the epitaxial layer, characterized in that the thermally conducting layer, on the bottom side of the epitaxial layer, contacts at least 80%, preferably at least 90%, particularly preferably at least 95%, and in particular 100%, of the bottom side of the epitaxial layer.

The transistor exhibits no back-gating and is free of problems that arise from a buffer stack for the lattice and strain adaptation, conductivity on the back side, heat dissipation, uncontrolled potential on the back side, and static back-gating, that is, free of typical drawbacks of known transistors that comprise an AlGaN—GaN HEMT on an Si substrate. This offers the advantage of greater design flexibility since multiple functionalities, such as full-bridge and half-bridge modules, bidirectional switching transistors and drivers, can be integrated on one transistor.

Furthermore, the thermal resistance of the transistor according to the invention is considerably improved, and the possibility of leakage or breakdown mechanisms related to the insufficient insulation properties of a carbon-doped GaN are reduced. In addition, the structure of the transistor is not very complicated.

Apart from this, the total electric power of the transistor is higher. This results from the fact that lateral GaN-on-Si transistors, which were only produced by locally removing substrate, already exhibit a 3 kV operation, that is, power that already exceeds that of actual SiC components. With the transistor according to the invention, total electric power levels in excess of 3 kV are possible.

The transistor according to the invention can be produced by way of the method according to the invention. This means that the transistor according to the invention can have features that the transistor necessarily has as a result of carrying out the method according to the invention. The features described above in connection with the method according to the invention can consequently also be features of the transistor according to the invention.

The subject matter according to the invention shall be described in more detail based on the following figures, without limiting the subject matter to the specific embodiments illustrated here.

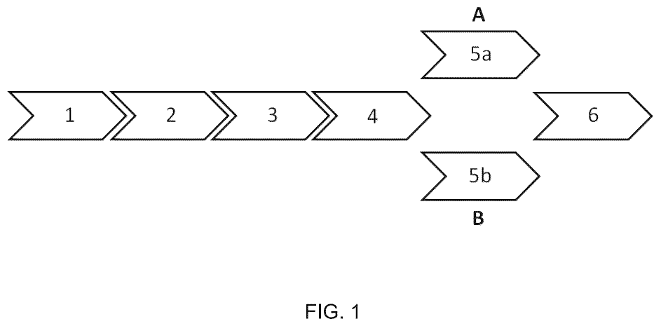

FIG. 1 shows a sequence of the method for producing a lateral or vertical membrane power transistor. After a transistor epitaxy 1 has been carried out on a substrate, a complete front-end process of the transistor 2 is carried out. This is followed by bonding 3 to a temporary wafer, the substrate thereafter being completely removed 4. Subsequently, a method step A is carried out during the production of a lateral transistor, in which bonding 5a to an electrically insulating, thermally conductive substrate takes place, and a method step B is carried out during the production of a vertical transistor, in which the steps of back-side contacting and bonding 5b to an electrically conductive and thermally conductive substrate take place. In both cases A, B, a detachment 6 of the temporary wafer follows at the end.

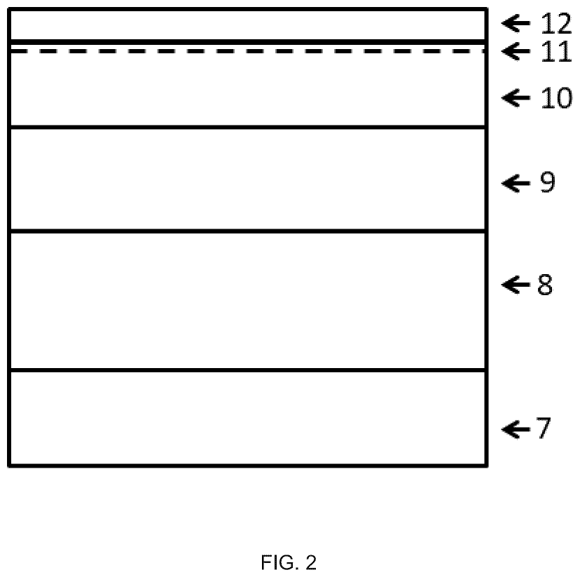

FIG. 2 shows a schematic illustration of the epitaxial layers of a lateral GaN HEMT. Buffer layers 8 are arranged on the conductive Si substrate 7 for lattice and strain matching. An insulating GaN:C layer 9 is situated on the buffer layers 8. A GaN UID layer 10, serving as a channel, is arranged on the insulating GaN:C layer 9, An AlGaN UID layer 12, serving as a barrier, is situated on the GaN UID layer 10, wherein a 2DEG layer 11 forms between the GaN UID layer 10 and the AlGaN UID layer 12.

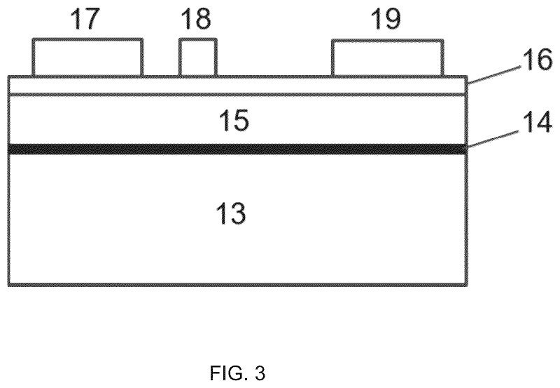

FIG. 3 shows a schematic illustration of a lateral GaN HEMT, which is transferred onto an insulating and thermally conductive AlN wafer. An AlN wafer 13 is connected to a GaN-based buffer 15 via a bond interface 14. An AlGaN barrier 16 is arranged on the GaN-based buffer 15. A source 17, a gate 18 and a drain 19 are situated on the AlGaN barrier 16.

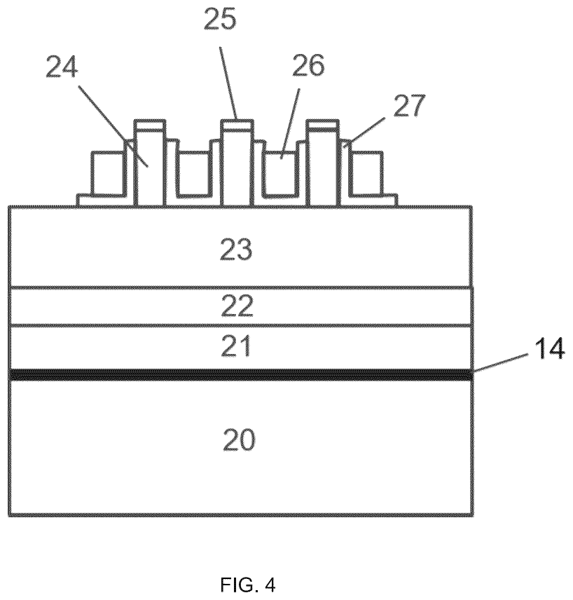

FIG. 4 shows a schematic illustration of a vertical GaN FinFET, which is transferred onto an electrically and thermally conductive substrate. A conductive Si or metal wafer 20 is connected to a drain contact 21 via a bond interface 14. A n⁺ GaN drain layer 22 is present on the drain contact 21, and a n⁻ GaN drift zone 23 is present on the n⁺ GaN drain layer 22. A GaN-Fin structure 24, a source contact 25, a gate metal 26 and a gate insulator 27 are arranged on the n⁻ GaN drift zone 23.

### LIST OF REFERENCE SIGNS

1: transistor epitaxy;
2: complete front-end process of the transistor;
3: bonding onto temporary substrate (e.g., temporary wafer);
4: complete removal of the substrate;
5a: bonding onto an electrically insulating, thermally conductive substrate;
5b: back-side contacting and bonding onto electrically and thermally conductive substrate;
6: detachment of the temporary substrate (e.g., temporary wafer);
7: Si substrate (conductive);
8: buffer layers (lattice and strain matching);
9: GaN:C (insulating);
10: GaN UID (channel);
11: 2DEG;
12: AlGaN UID (barrier);
13: AlN wafer;
14: bond interface;
15: GaN-based buffer;
16: AlGaN barrier;
17: source;
18: gate;
19: drain;
20: conductive Si or metal wafer;
21: drain contact;
22: n⁺ GaN drain;
23: n⁻ GaN drift zone;
24: GaN-Fin structure;
25: source contact;
26: gate metal;
27: gate insulator;
A: method step during the production of a lateral transistor;
B: method step during the production of a vertical transistor.

1-15. (canceled)

16. A method for producing a transistor with high electron mobility, comprising:
a) growing an epitaxial layer, which comprises a semiconductor material, onto a front side of a flat substrate, wherein the flat substrate is
i) removable from the epitaxial layer by chemical etching and/or dry etching; and/or
ii) removable from the epitaxial layer by application of laser radiation having a certain wavelength;
b) applying at least one lateral and/or vertical transistor structure to a front side of the epitaxial layer;
c) applying a temporary wafer to the front side of the epitaxial layer;
d) removing the flat substrate from the bottom side of the epitaxial layer;
e) applying a thermally conducting layer to the bottom side of the epitaxial layer; and
f) completely removing the temporary wafer;
wherein the flat substrate is completely removed from the bottom side of the epitaxial layer, and the thermally conducting layer is applied to the bottom side of the epitaxial layer so that the thermally conducting layer contacts at least 80% of the bottom side of the epitaxial layer.

17. The method according to claim 16, wherein the epitaxial layer
i) comprises a semiconductor material selected from the group consisting of GaN, AlN, AlₓGa₁₋ₓN, InGaN, InAlGaN, AlScN, Ga₂O₃ and combinations thereof, wherein x is a number between 0 and 1, the semiconductor material optionally comprising a doping; and/or
ii) is grown on in the direction of the flat substrate up to a height in the range of 200 nm to 50 μm; and/or
iii) has an extension of 25.4 mm to 300 mm in a direction parallel to the flat substrate.

18. The method according to claim 16, wherein the flat substrate
i) is suitable for growing epitaxially a layer comprising a material selected from the group consisting of GaN, AlN, AlₓGa₁₋ₓN, InGaN, InAlGaN, AlScN, Ga₂O₃ and combinations thereof, each of said material is optionally doped, with x being a number between 0 and 1; and/or
ii) comprises a material selected from the group consisting of silicon carbide, AlN, sapphire, and combinations and mixtures thereof.

19. The method according to claim 16, wherein the flat substrate has a height in the range of 100 μm to 1.5 mm in the direction of the epitaxial layer.

20. The method according to claim 16, which comprises applying at least one electrical front contact to an upper side of the epitaxial layer.

21. The method according to claim 20, wherein the application of the at least one electrical front contact is carried out
i) after the application of at least one lateral and/or vertical structure, which is selected from the group consisting of transistor, Schottky diode structure, p-n diode structure, PIN diode structure, and combinations thereof, to the epitaxial layer, or after the removal of the temporary wafer; and/or
ii) by utilizing a material that has an electrical conductivity in the range of 10⁻⁶ Ωm to 10⁻⁸ Ωm; and/or
iii) by utilizing a material that has a thermal conductivity in the range of 10 to 2300 W/(m·K); and/or
iv) by utilizing a material that comprises a metal; and/or
v) in such a way that the at least one electrical front-side contact has a height in the range of 50 nm to 10 μm in the direction of the epitaxial layer; and/or
vi) by way of deposition or bonding.

22. The method according to claim 16, wherein the at least one lateral and/or vertical transistor structure
i) is applied in the form of a layer; and
ii) comprises a semiconductor; and/or
iii) is processed by a step selected from the group consisting of demetallization, wet-chemical etching, dry-chemical etching, insulator coating, ion implantation, diffusion, and combinations thereof.

23. The method according to claim 16, wherein the temporary wafer is applied to the front side of the epitaxial layer by gluing.

24. The method according to claim 16, wherein the complete removal of the flat substrate from the bottom side of the epitaxial layer is effected by
i) chemical etching, dry etching, and combinations thereof; and/or
ii) applying laser radiation having a certain wavelength.

25. The method according to claim 16, wherein the thermally conducting layer on the bottom side of the epitaxial layer
i) comprises a material that has a specific thermal conductivity in the range of 10 to 2300 W/(m K); and/or
ii) has been or is applied by way of deposition or bonding.

26. The method according to claim 16, wherein the thermally conducting layer on the bottom side of the epitaxial layer comprises a material that is electrically insulating.

27. The method according to claim 26, wherein the electrically insulating material
i) has a specific electrical resistance of at least 10¹⁰ Ωm; and/or
ii) is selected from the group consisting of AlN, TaC, SiN, diamond, and combinations thereof; and/or
iii) has a height in the range of 20 μm to 1.5 mm in the direction of the epitaxial layer.

28. The method according to claim 16, wherein the thermally conducting layer on the bottom side of the epitaxial layer comprises a material that is electrically conductive.

29. The method according to claim 28, wherein the material that is electrically conductive
i) has a specific electrical resistance of no more than 2·10⁻⁴ Ωm; and/or
ii) contacts an n⁺-doped region of the epitaxial layer; and/or
iii) comprises a semiconductor material and/or metal; and/or
iv) has a height in the range of 50 nm to 5 μm in the direction of the epitaxial layer.

30. The method according to claim 16, wherein the method comprises applying at least one electrical back-side contact to a bottom side of the epitaxial layer.

31. The method according to claim 30, wherein the electrical back-side contact
i) is applied to the bottom side of the epitaxial layer after the flat substrate has been removed, optionally after a local region of the thermally conducting layer has been removed; and/or
ii) comprises a material that has a specific electrical resistance of no more than 2·10⁻⁴ ohm·m; and/or
iii) comprises a material that has a specific thermal conductivity in the range of 150 to 380 W/(m·K); and/or
iv) comprises a semiconductor material and/or metal.

32. The method according to claim 16, wherein the complete removal of the temporary wafer from the upper side of the epitaxial layer is effected by a method selected from the group consisting of laser lift-off method, wet-chemical etching method, dry-chemical etching method, thermal method, thermally activated smart-cut method, and combinations thereof, optionally combined with an ion implantation method.

33. A transistor with high electron mobility, comprising:
a) an epitaxial layer, which comprises a semiconductor material; and
b) at least one lateral and/or vertical transistor structure on an upper side of the epitaxial layer; and
c) a thermally conducting layer on a bottom side of the epitaxial layer,
wherein the thermally conducting layer, on the bottom side of the epitaxial layer, contacts at least 80% of the bottom side of the epitaxial layer.

34. A transistor produced by the method of claim 16.
